(19) United States
(12) Patent Application Publication
(10) Pub. No.: US 2007/0051946 A1
(43) Pub. Date: Mar. 8, 2007

(54) Organic Light-Emitting Diodes and an Arrangement with Several Organic Light-Emitting Diodes

(75) Inventors: Karsten Walzer, Dresden (DE); Teja Roch, Dresden (DE); Qiang Huang, Dresden (DE); Karl Leo, Dresden (DE)

Correspondence Address: SUTHERLAND ASBILL & BRENNAN LLP, 999 PEACHTREE STREET, N.E., ATLANTA, GA, 30309, US

(73) Assignee: NOVALED AG, Dresden (DE)

(21) Appl. No.: 11/426,798

(22) Filed: Jun. 27, 2006

(30) Foreign Application Priority Data
Jul. 1, 2005 (EP) EP 05014318.9

(51) Int. Cl. H01L 29/08

(52) U.S. Cl. 257/40

(57) ABSTRACT

Organic light-emitting diode with a layer arrangement which comprises an electrode, a counter electrode and an organic layer sequence arranged between the electrode and the counter electrode, where the organic layer sequence is arranged on a metal substrate and one or several organic transport layers containing in each case an admixture for increasing the electric conductivity and which are formed with at least one of the features from the following group of features: charge carrier transporting and charge carrier injecting.

The invention lies in the field of electroluminescent light-emission facilities.

### BACKGROUND OF THE INVENTION

Since the demonstration of low working voltages by Tang et al. [C. W. Tang et al.: Appl. Phys. Lett. 51 (12), 913 (1987)], organic light-emitting diodes (OLED) have become promising candidates for the realisation of large-surface displays and illuminating elements. They comprise a series of thin (typically 1 nm to 1 μm) layers consisting of organic materials which are preferably vapour-deposited in a vacuum or spin-coated in their polymer form. Following electric contacting by means of electrically conductive layers, they form varied components such as light-emitting diodes, displays and lighting elements. With their respective characteristics, they provide competition for the established components on the basis of inorganic layers.

In the case of the organic light-emitting diodes, and by means of the injection of charge carriers (electrons from the one side and holes from the other), from the contacts into the adjoining organic layers as a result of an externally applied voltage, the following formation of exitones (electron-hole-pairs) in an active zone and the radiating recombination of these exitones, light is generated and emitted from the light-emitting diode. Normally, organic light-emitting diodes consist of a series of several layers. This applies in particular for components prepared in the vacuum by means of vapour-depositing where the functions charge carrier injection from the electrodes, charge carrier transport and emission frequently take place in various layers.

The advantage of such components on an organic basis compared with the conventional components on an inorganic basis (semi-conductors such as silicon, gallium arsenide) is that it is possible to manufacture very large-surface elements, meaning, large display elements (monitors, screens) or lighting elements. The organic basic materials are relatively inexpensive compared to inorganic materials (low level material and energy requirement). Moreover, these materials can be deposited onto flexible or freely formable substrates because of their low process temperature compared with inorganic materials. This fact opens the way to a complete series of novel applications in the display and lighting technology.

According to the state of the art, organic light-emitting diodes are usually deposited onto glass substrates which are coated with a transparent conducting oxide layer (usually indium tin oxide, ITO). As a result of many applications, however, the costs of this substrate and the conducting layers are too high: firstly, the necessary high-quality glass itself causes high costs; secondly, the electrically conductive oxides are relatively expensive. For these reasons it would be very advantageous if it were possible to realise an organic light-emitting diode on inexpensive substrates. In this case there is normally the problematic situation where the lights emitting diode, as ever, must be provided with a contact. This requires that, at first, a substrate must be provided with an insulating layer and then again an electrode layer has to be applied which serves as a base electrode for the organic light-emitting diode. A further disadvantage of the conventional organic light-emitting diode is the usually selected arrangement with a transparent substrate: the light emission of the light-emitting diode is effected in this case through the transparent electrode and the substrate whereas the oppositely located contact (the substrate in most cases) is impermeable to light and is highly reflective in the spectral area concerned. For the application, subsequently, a high-transparent substrate and transparent contact layers are necessary which in many cases restrict the substrate selection to a major extent and prevent the selection of particularly inexpensive substrates.

Proposals for organic light-emitting diodes on metallic substrates have already been made. These substrates have a variety of advantages. Firstly, metallic substrates can be manufactured relatively inexpensively depending on the circumstances. Secondly, the high thermal conductivity of metallic substrates can contribute towards a good discharge transport of the heat. Thirdly, metallic substrates can be executed relatively thin and are flexible as a result.

In the document U.S. Pat. No. 6,835,470 an organic light-emitting diode on a metal foil is proposed, preferably steel foil. The light-emitting diode is realised where at first an insulating layer is deposited onto the substrate, and after this a conductive electrode. The known arrangement envisages that the metal substrate is the negative electrode.

### SUMMARY OF THE INVENTION

The task of the invention is to state and present an organic light-emitting diode and an arrangement with several organic light-emitting diodes with a simplified structural configuration.

This task is solved according to the invention by means of an organic light-emitting diode according to the independent Claim 1 as well as by an arrangement with several organic light-emitting diodes according to the independent Claim 28.

According to one aspect of the invention, an organic light-emitting diode is created with a layer arrangement which comprises an electrode, a counter electrode and an organic layer sequence arranged between the electrode and the counter electrode, the organic layer sequence being arranged on a metal substrate and one or several organic transport layers containing in each case an admixture for increasing the electric conductivity and which are formed with at least one of the features from the following group of features: transporting charge carriers and injecting charge carriers.

According to a further aspect of the invention, an arrangement with several organic light-emitting diodes is created where the several organic light-emitting diodes are formed on individual and electrically separated areas of a metal substrate by partially providing the metal substrate with an insulating layer for the formation of the electrically separated areas.

Based on the usage of one or several electrically doped transport layers, a higher roughness of the metal substrate or of conductive or insulating layers separated thereon can be acceptable.

By means of the use of the metal substrate, a simplified structural configuration of the organic light-emitting diode is created which, in particular, can also be manufactured inexpensively because an inexpensive metal substrate can be deployed instead of the usually applied substrate materials. The metal substrate can be coated with the layers of the organic light-emitting diode in an uncomplicated manner, for example in a roll-to-roll method.

The organic layer sequence comprises one or several organic layers which are charge-carrier-injecting and/or charge-carrier-transporting and formed with an admixture (doping) for the purpose of increasing the electric conductivity. In a shorter form, such layers are also designated partially, in the following, as transport layers.

The use of such admixtures (doping) for the improvement of the electric properties of a matrix material as such is known (cf. DE 100 58 578). It was found that such doped layers are particularly advantageous because metal substrates, particularly with an inexpensive manufacture method, are usually characterised by a high degree of roughness. Examinations have surprisingly shown that, with the use of doped charge carrier transport layers, this roughness is more tolerable than in nondoped organic light-emitting diodes. This observation is explainable by the fact that the currents in non-doped organic light-emitting diodes are normally limited by space charges and therefore depend cubically on the layer thickness. However, in a doped transport layer the current depends linearly on the thickness so that layer thickness fluctuations have significantly less effect by means of a rough substrate.

Furthermore, with doped transport layers it is possible to freely select the thickness of the transport layer and, in particular, to select even thicker without the disadvantage of a higher operating voltage. In this way, layer thicknesses of up to 500 nm can be realised without any problems. Then again, the danger of short circuits caused by metallic needles on the substrate is reduced as a result. With these thicker transport layers it is furthermore possible to optimise the optic extraction of the light-emitting diode. This is particularly important on metal substrates because the high reflections on these substrates led to the situation where the constructive superimposition of the light emission in both directions is particularly important. With a doped transport layer, and due to the almost free selection of the layer thickness, it is possible to select this in such a way that there is a particularly favourable constructive interference for the light generated in the organic layer sequence where even the spectral location of the emitted light can be frequently optimised. With most of the organic light-emitting diodes, for example, the distance of the emission zone from the reflecting electrode is selected in such a way that a constructive interference results. This is normally the case when the distance to the electrode amounts to about one quarter of the wavelength. With the use of doped transport layers it is possible to select a higher order of the constructive interference, for example three quarters of the wavelength, and to maintain in this way the favourable properties with reduced probability of short circuits by the rough substrate.

In addition, and with the use of doped transport layers, it is possible to select the material of the base contact relatively independent of its work function which, contrary to organic light-emitting diodes with non-doped transport layers that require the highest possible work function of the substrate on the anode side, enables the option of selecting the substrate material according to other criteria such as, for example, the price, optical properties and processability. In particular, it will be possible to use also metals such as aluminium or silver as an anode.

A preferred further development of the invention envisages that a plane-surface electrical contact is formed between the metal substrate and the organic layer sequence and this said contact is insulation layer free.

With a purposeful embodiment of the invention, it can be envisaged that the metal substrate is coated with a layer smoothening a surface of the metal substrate where this said layer selectively consists of a varnish or a polymer material.

A preferred further development of the invention envisages that the organic layer sequence is deposited directly onto the metal substrate, and with the metal substrate, the electrode is formed.

A preferred further development of the invention envisages that the electrode is formed as an electrically conducting layer on the metal substrate.

With a purposeful embodiment of the invention, it can be envisaged that the electrode is a positive electric contact and the counter electrode a negative electric contact.

An advantageous embodiment of the invention envisages that the electrode is the negative electric contact and the counter electrode the positive electric contact.

A preferred further development of the invention envisages that the electrically conducting layer consists at least partially of silver.

A preferred further development of the invention envisages that the metal substrate consists of aluminium.

With a purposeful embodiment of the invention it can be envisaged that the metal substrate consists of steel.

An advantageous embodiment of the invention envisages that the metal substrate is flexible.

A preferred further development of the invention envisages that a charge carrier transporting layer facing the metal substrate is formed with a layer thickness supporting a light emission by means of constructive emission.

A preferred further development of the invention envisages that the layer thickness of charge carrier transporting layer facing the metal substrate is at least ¾λ, where λ is the emission wavelength of light which is emitted from the layer arrangement.

With a purposeful embodiment of the invention it can be envisaged that a charge carrier transporting layer facing away from the metal substrate is formed with a layer thickness supporting a light emission by means of constructive emission.

An advantageous embodiment of the invention envisages that a charge carrier transporting layer is formed in a smoothened manner.

A preferred further development of the invention envisages that a charge carrier transporting layer receives as a matrix material C₆₀.

A preferred further development of the invention envisages that the metal substrate has a structure improving an optical extraction of light generated in the organic layer sequence, which structure is selectively formed as a periodic or a non-periodic structure.

With a purposeful embodiment of the invention it can be envisaged that there can be a transparent layer system with one or more layers on a top electrode for protection against environmental influences.

An advantageous embodiment of the invention envisages that the transparent layer system is applied by lamination.

A preferred further development of the invention envisages that the layer arrangement is formed in a white-light emitting manner.

A preferred further development of the invention envisages that light emitting layers which are enclosed by the organic layer sequence are formed with various emitter materials according to one or more of the following configurations: laterally arranged strips, periodic geometrical elements and none periodic geometrical elements.

With a purposeful embodiment of the invention, an optically scattering layer can be envisaged.

An advantageous embodiment of the invention envisages that the layer arrangement is deposited monolithically on the metal substrate.

A preferred further development of the invention envisages that the smoothening layer is electrically insulating.

A preferred further development of the invention envisages that several organic light-emitting diode units are stacked monolithically one over the other and the layer arrangement is formed in a white-light emitting manner.

With a purposeful embodiment of the invention it can be envisaged that the layer arrangement is manufactured continually from roll-to-roll. An advantageous embodiment of the invention envisages that, in this case, the width of the metal substrate lies between 1 cm and approx. 6 m.

In a roll-to-roll plant, the substrates (metal substrates) are rolled off a roll. In a vacuum and in sequential order, for example from linear sources, the organic layers and the cathode are deposited and then, after depositing several layers for encapsulation, the finished product is again rolled onto a roll. The principle of a roll-to-roll manufacture of OLED-displays on transparent substrates and a possible plant for this purpose are described as such in the document EP 1 115 268 A1. The technically sophisticated case described therein can be realised more inexpensively and in an uncomplicated manner by the manufacture of top-emitting OLEDs according to Claim 1 as inexpensively manufactured large-scale technical metal foils roll-to-roll are coated with OLEDs. In a further characterisation of the invention, OLEDs according to Claim 1 are used for lighting purposes which selectively contain structured, non-structured or stacked OLEDs. In this case it is also possible to integrate into this process the necessary structuring with an insulating layer for obtaining segregated organic light-emitting diodes, for example by means of printing of polymer insulating layers, by means of the separation of insulating layers with the help of local evaporating or sputtering, or by means of evaporating or sputtering through a shadow mask.

An advantageous embodiment of the invention envisages that the several organic light-emitting diodes are formed on individual and electrically separated areas of a metal substrate by partially providing the metal substrate with an insulating layer for forming the electrically separate areas.

A preferred further development of the invention envisages that the insulting layer is imprinted onto the metal substrate.

A preferred further development of the invention envisages that the insulating layer is vapour-deposited onto the metal substrate.

With a purposeful embodiment of the invention, it can be envisaged that the insulating layer is sputtered onto the metal substrate.

An advantageous embodiment of the invention envisages that the insulating layer is laminated onto the metal substrate.

A preferred further development of the invention envisages that an electrode facing the metal substrate is split up into strip elements by means of further insulating layers, and a counter electrode facing away from the metal substrate is subdivided into further strip elements vertical to the strip elements, so that individually controllable image points of a passive matrix arrangement are formed.

A preferred further development of the invention envisages that the counter electrode is subdivided into laterally limited elements.

With a purposeful embodiment of the invention it can be envisaged that a layer arrangement of the several organic light-emitting diodes is continually manufactured on one band from roll-to-roll, and the strip elements are formed in such a way that vaporising sources emit spatially separate vapour lobes transverse to the band.

In a preferred characterisation, doped transport layers can be used, which develop a smoothening effect by forming the transport layers as smoothening layer. Based on the ohmic current transport in such layers, the danger of local current paths with excessively increased current currents, which can lead to short-circuits and to the destruction of the component, is reduced.

Further preferred embodiments use an organic light-emitting diode where the optic extraction is increased by means of a specific roughening or structuring of the substrate. With customary planar light-emitting diode there is the problem that essential parts of the light emission do not go into external modes but rather into substrate modes or film modes of the organic light-emitting diode. With the use of metal substrates with optic extraction away from the substrate (top emitter), the substrate modes are already suppressed The propagation of light in a film mode can be suppressed by providing the substrate with a periodic or non-periodic roughness. This is particularly possible in a very uncomplicated manner with a roll-to-roll production because, in this case for example, a direct forming of the substrate during the rolling process with a roll is possible; in favourable cases the structure that normally and unintentionally occurs in a rolling process can be advantageously used. The substrate itself serves as a rough layer without the necessary of applying an additional rough electrode layer onto a substrate, so that the arrangement is particularly advantageous for a non-sophisticated production process.

It can be furthermore envisaged to realise also an arrangement of image points on a metal foil, for example, a passive matrix display. In this case, the lower electrode is subdivided into strips; vertical to this the upper electrode is also vapour-deposited in strips. With this arrangement the individual image points can be activated and an alternating image information can be displayed.

A particularly favourable arrangement for the production of spectrally broad or white light is where individual segments of light-emitting diodes are arranged with different emission spectrum next to one another. In this way it is possible to efficiently produce spectral broadband light. This arrangement can take place in strips or in other periodically or non-periodically repeated elements. In order to have the component appear to the observer as being homogenously emitting to the greatest possible extent, it is also possible to deposit an optically scattering layer onto the arrangement. This layer can be separated directly onto the arrangement or can be applied by laminating or by means of an adhesive method. A particularly favourable arrangement is to design the layers as necessary for the encapsulation in such a way that they simultaneously take over the function of the optical scattering.

### DESCRIPTION OF PREFERRED EMBODIMENT EXAMPLES OF THE INVENTION

The invention is explained as follows in greater detail on the basis of embodiment examples with reference to the Figures of a drawing. The Figures show the following:

FIG. 1: a current-voltage characteristic curve for organic light-emitting components according to one embodiment of the invention;

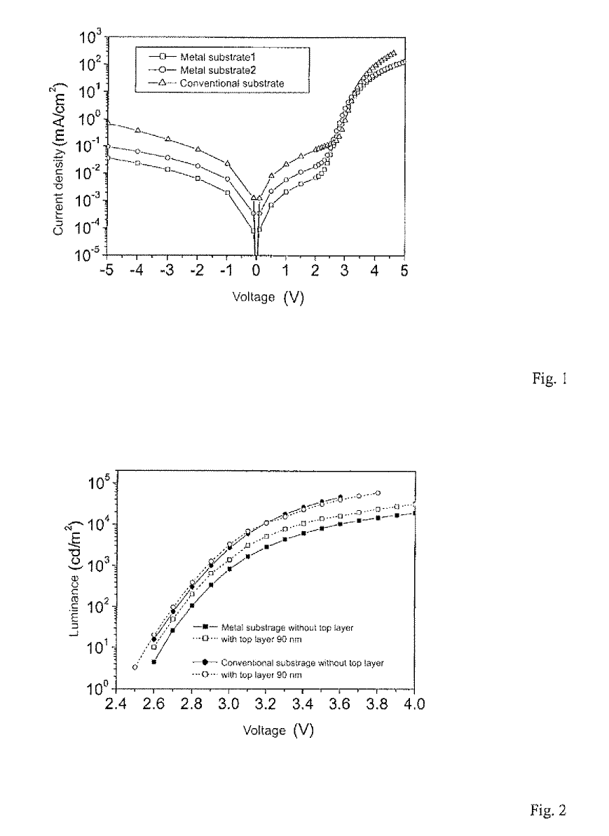

FIG. 2: a luminance-voltage characteristic curve for organic light-emitting components according to a further embodiment of the invention;

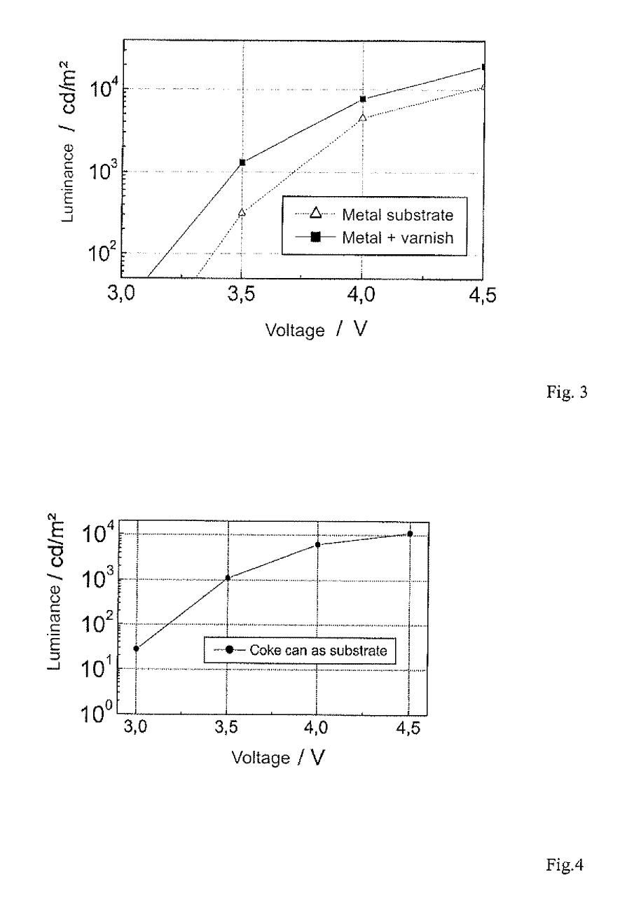

FIG. 3: a luminance-voltage characteristic curve for organic light-emitting components according to another embodiment of the invention with a smoothening intermediate layer, and

FIG. 4: an illustration and a luminance-voltage characteristic curve for an organic light-emitting component on an industrially produced substrate (Coke can).

In the following description, charge carriers transporting/injecting layers are designated as hole transport or electron transport layer, namely according to the preferred or essentially exclusively conducted or transported type of the charge carriers through the corresponding layer.

### EMBODIMENT EXAMPLE 1

An embodiment for a blue-emitting OLED comprises the following layers:
1 Substrate, aluminium foil
2 Silver layer, sputtered
3 Hole transport layer. Spiro-TTB, p-doped with 2% NDP-2, 35 nm thick
4 Electron block layer, Spiro-TAD, 10 nm
5 Emitter layer—blue emitter, 20 nm
6 Electron transport layer, BPhen, 10 nm
7 Electron transport layer, BPhen, n-doped with Cs in the ratio 1:1, 130 nm
8 Transparent cathode, Ag vapour-deposited, 15 nm

FIG. 1 shows a current-voltage characteristic curve of two organic light-emitting components of this type (squares and circles); as a comparison to this, a similar component (triangles) is shown that was realised on a high-quality glass substrate with a Cr/Ag-contact produced under clean room conditions. It is obvious that the OLEDs have blocking characteristic curves that are significantly better. The surprising aspect here is the fact that this effect merely requires an unusually thick electron transport layer.

### EMBODIMENT EXAMPLE 2

An embodiment for a green-emitting OLED comprises the following layers:
10 Substrate, aluminium foil
11 Silver layer, sputtered
12 Hole transport layer: Spiro-TTB, p-doped with 2% NDP-2, 48 nm thick
13 Electron block layer, Spiro-TAD, 10 nm
14 Emitter layer I, TCTA: Ir(ppy)₃ (9%), 5 nm
15 Emitter layer IT, TPBI: Ir(ppy)₃ (9%), 10 nm
16 Electron transport layer, BPhen, 10 nm
17 Electron transport layer, BPhen, n-doped with Cs in the ratio 1:1, 130 nm
18 Transparent cathode, Ag vapour-deposited, 15 nm
19 Cover layer: Spiro-TTB, 90 nm

FIG. 2 shows a luminance-voltage characteristic curve of two organic light-emitting components according to the second embodiment (squares and circles, each with and without layer 19). The brightness of 100 Cd/m² is already obtained at 2.9 V, the maximum performance efficiency is 50 lm/W at 10,000 Cd/m². This shows that OLEDs can be realised with excellent parameters on metallic substrates.

The embodiments as stated above have in common that no insulating layer whatsoever is formed between the metal substrate and the lowest layer of the organic layer sequence. As an alternative to the embodiments stated herein, it can be envisaged that the organic layer sequence is deposited directly onto the metal substrate so that with the metal substrate, for example the aluminium foil, the lower electrode of the organic light-emitting diode is formed. In this way, the material for forming an electrode produced separately from the metal substrate is saved. In addition, a process step necessary in this case for the production of the organic light-emitting diode can be saved.

### EMBODIMENT EXAMPLE 3

In an embodiment 3, it is shown how an additional varnish layer on a metal substrate contributes to reduced leakage currents and, subsequently, to improved electrical properties. At the same time, a thick p-side is used which contributes towards a further homogenisation of the surface. For this purpose, FIG. 3 compares two OLEDs that are similar in design with the following structure where one was executed with and one was executed without a smoothening layer 21.
20 Substrate, aluminium foil,
21 Smoothening layer, varnish (optional)
22 Silver layer, sputtered
23 Hole transport layer: MeO-TPD, p-doped with 4% F4-TCNQ, 150 nm thick
24 Electron block layer, Spiro-TAD, 10 nm
25 Emitter layer, TCTA: Ir(ppy)₃ (8%), 20 nm
26 Electron transport layer, BPhen, 10 nm
27 Electron transport layer, BPhen, n-doped with Cs in the ratio 1:1, 30 nm
28 Transparent cathode, Ag vapour-deposited, 15 nm

As can be seen in FIG. 3, a further improvement of the luminance-voltage characteristic can be obtained with the use of an additional smoothening layer, for example varnish, on the metal substrate. It must be emphasised that, with the simultaneous use of thick doped transport layers, the low operating voltages and subsequent performance efficiencies are enabled.

### EMBODIMENT EXAMPLE 4

In a further characterisation, objects for lighting or advertising purposes can be involved, for example, which contain a metal substrate, an organic light-emitting diode and at least one doped charge carrier transport layer. A Coke can is shown here as an example which serves as a substrate for an OLED according to the Claims of the patent as presented here, serving successfully as an OLED-substrate.

Layer structural configuration:
30 Substrate, Coke can (sheet metal with varnish)
31 Silver layer, sputtered
32 Hole transport layer, MeO-TPD, p-doped with 4% F4-TCNQ, 150 nm thick
33 Electron block layer, Spiro-TAD, 10 nm
34 Emitter layer, TCTA: Ir(ppy)₃ (8%), 20 nm
36 Electron transport layer, TPBi, 10 nm
37 Electron transport layer, BPhen, n-doped with Cs in the ratio 1:1, 30 nm
38 Transparent cathode, Ag vapour-deposited, 15 nm

However, it can also be advantageous to provide a substrate with further layers. These include, for example, dielectric layers which can be used for example for increasing the reflection, or insulating organic intermediate layers. A particularly advantageous arrangement is, for example, a dielectric layer with a follow-up thin silver layer as an electrode. Such an arrangement is also particularly advantageous for the passive matrix arrangement as mentioned.

The features of the invention as disclosed in this description, in the claims and in the drawings can be of significance both individually as well as in random combination for the realisation of the invention in its various embodiment forms.

1. Organic light-emitting diode with a layer arrangement which comprises an electrode, a counter electrode and an organic layer sequence arranged between the electrode and the counter electrode, where the organic layer sequence is arranged on a metal substrate and one or several organic transport layers containing in each case an admixture for increasing the electric conductivity and which are formed with at least one of the features from the following group of features: charge carrier transporting and charge carrier injecting.

2. Organic light-emitting diode according to claim 1, characterized in that a plane surface electric contact is formed between the metal substrate and the organic layer sequence, which contact is insulation-layer-free.

3. Organic light-emitting diode according to claim 1, characterized in that the metal substrate is coated with a layer that smoothens a surface of the metal substrate, which layer consists of a varnish or a polymer material, as desired.

4. Organic light-emitting diode according to claim 1, characterized in that the organic layer sequence is directly deposited onto the metal substrate and, with the metal substrate, the electrode is formed.

5. Organic light-emitting diode according to claim 1, characterized in that the electrode is formed as an electrically conducting layer on the metal substrate.

6. Organic light-emitting diode according to claim 1, characterized in that the electrode is a positive electric contact and the counter electrode is a negative electric contact.

7. Organic light-emitting diode according to claim 1, characterized in that the electrode is the negative electric contact and the counter electrode is the positive electric contact.

8. Organic light-emitting diode according to claim 6, characterized in that the electrically conducting layer consists at least partially of silver.

9. Organic light-emitting diode according to claim 1, characterized in that the metal substrate consists of aluminium.

10. Organic light-emitting diode according to claim 1, characterized in that the metal substrate consists of steel.

11. Organic light-emitting diode according to claim 1, characterized in that the metal substrate is flexible.

12. Organic light-emitting diode according to claim 1, characterized in that a charge carrier transporting layer facing the metal substrate is formed with a layer thickness supporting a light emission by means of constructive emission.

13. Organic light-emitting diode according to claim 12, characterized in that the layer thickness of the charge carrier transporting layer facing the metal substrate is at least ¾λ, where λ is the emission wavelength of light which is emitted from the layer arrangement.

14. Organic light-emitting diode according to claim 1, characterized in that a charge carrier transporting layer facing away from the metal substrate is formed with a layer thickness supporting a light emission by means of constructive emission.

15. Organic light-emitting diode according to claim 1, characterized in that a charge carrier transporting layer is formed in a smoothening manner.

16. Organic light-emitting diode according to claim 1, characterized in that a charge carrier transporting layer contains C₆₀ as a matrix material.

17. Organic light-emitting diode according to claim 1, characterized in that the metal substrate has a structure improving an optical extraction of light generated in the organic layer sequence, which structure is formed as a periodic or a non-periodic structure, as desired.

18. Organic light-emitting diode according to claim 1, characterised by a transparent layer system with one or several layers on a top electrode for protection against environmental influences.

19. Organic light-emitting diode according to claim 18, characterized in that the transparent layer system is applied by lamination.

20. Organic light-emitting diode according to claim 1, characterized in that the arrangement is formed in a white-light emitting manner.

21. Organic light-emitting diode according to claim 1, characterized in that light emitting layers which are enclosed by the organic layer sequence are formed with various emitter materials according to one or more of the following configurations: laterally arranged strips, periodic geometrical elements and non-periodic geometrical elements.

22. Organic light-emitting diode according to claim 21, characterized by a optically scattering layer.

23. Organic light-emitting diode according to claim 1, characterized in that layer arrangement is monolithically deposited on the metal substrate.

24. Organic light-emitting diode according to claim 3, characterized in that the smoothening layer is electrically insulating.

25. Organic light-emitting diode according to claim 1, characterized in that several organic light-emitting diode units are stacked monolithically one over the other and the layer arrangement is formed in a white-light emitting manner.

26. Organic light-emitting diode according to claim 1, characterized in that layer arrangement is produced continually from roll-to-roll.

27. Arrangement with several organic light-emitting diodes according to claim 1, characterized in that the several organic light-emitting diodes are formed on individual and electrically separated areas of a metal substrate by providing the metal substrate with an insulating layer for forming the electrically separated area.

28. Arrangement according to claim 27, characterized in that the insulating layer is imprinted on the metal substrate.

29. Arrangement according to claim 27, characterized in that the insulating layer is vapour-deposited onto the metal substrate.

30. Arrangement according to claim 27, characterized in that the insulating layer is sputtered onto the metal substrate.

31. Arrangement according to claim 27, characterized in that the insulating layer is applied to the metal substrate by means of lamination.

32. Arrangement according to claim 27, characterized in that an electrode facing the metal substrate is split up into strip elements by means of further insulating layers, and a counter electrode facing away from the metal substrate is subdivided into further strip elements vertical to the strip elements, so that individually controllable image points of a passive matrix arrangement are formed.

33. Arrangement according to claim 27, characterized in that the counter electrode is subdivided into laterally limited elements.

34. Arrangement according to claim 32, characterized in that a layer arrangement of the several organic light-emitting diodes is continually manufactured on one band from roll-to-roll, and the strip elements are formed in such a way that vaporising sources emit spatially separate vapour lobes transverse to the band.
